(19) United States
(12) Patent Application Publication
(10) Pub. No.: US 2023/0265012 A1
(43) Pub. Date: Aug. 24, 2023

(54) BONDED BODY MANUFACTURING METHOD AND BONDED BODY MANUFACTURING DEVICE

(71) Applicant: Nippon Electric Glass Co., Ltd., Otsu-shi, Shiga (JP)

(72) Inventors: Toru SHIRAGAMI, Otsu-shi (JP); Tatsuya NAGATA, Otsu-shi (JP)

(73) Assignee: Nippon Electric Glass Co., Ltd., Otsu-shi, Shiga (JP)

(21) Appl. No.: 17/766,634

(22) PCT Filed: Oct. 5, 2020
(86) PCT No.: PCT/JP2020/037696

§ 371 Date: May 10, 2023

(30) Foreign Application Priority Data
Oct. 10, 2019 (JP) 2019-187065

(51) Int. Cl. C03C 27/10; B32B 17/06; B32B 7/14; B32B 37/06; B32B 37/10; B32B 37/12; B32B 37/18; B32B 38/00

(52) U.S. Cl. CPC C03C 27/10; B32B 7/14; B32B 17/06; B32B 37/06; B32B 37/10; B32B 37/1207; B32B 37/1292; B32B 37/18; B32B 38/0004; B32B 2250/02; B32B 2307/412; B32B 2310/0843; B32B 2315/08; B32B 2457/12; B32B 2457/14; B32B 2457/206

(57) ABSTRACT

This invention has an object to enhance the whole adhesiveness of a bonding material to a glass member and a bonding target member. A method for manufacturing a bonded body (10) includes: a placing step of placing a laminate (11) on plural urging members (32) in a storage part (24) of a jig main body (20) so that its first surface (11a) faces the plural urging members and placing a pressing transparent member (28) on a second surface (11b) of the laminate; after the placing step, a pressing step of pressing the second surface of the laminate via the pressing transparent member, thereby causing the first surface of the laminate to be pressed by urging forces of the plural urging members; and a bonding part forming step of forming a bonding part from the bonding material while pressing the laminate by the pressing step, thereby yielding a bonded body.

### TECHNICAL FIELD

The present invention relates to a bonded body manufacturing method (i.e., a method for manufacturing a bonded body) and a bonded body manufacturing device.

### BACKGROUND ART

As disclosed in Patent Literature 1, there has been known a conventional method for bonding, via a bonding material, a glass member such as a glass lid to a member to be bonded (i.e., a bonding target member) such as a glass-ceramic container so as to manufacture a bonded body such as a package.

### CITATION LIST

### Patent Literature 1

Japanese Patent Application Publication Tokukai No.2014–236202 (Publication date: Dec. 15, 2014)

### SUMMARY OF INVENTION

### Technical Problem

In order to obtain a bonded body such as that described above, it is preferable to form a laminate made of a glass member, a bonding target member, and a bonding material interposed between the glass member and the bonding target member and then to bond the glass member and the bonding target member to each other by heating the bonding material while pressing the laminate in a thickness direction of the laminate. Carrying out the bonding while pressing the laminate can enhance bonding strength between the glass member and the bonding target member. However, for example, in a case where a pressure is applied locally to the laminate, the adhesiveness of the bonding material with respect to the glass member and the bonding target member may be partially impaired, and consequently the bonding strength may be reduced.

An aspect of the present invention was made in view of the above-discussed actual circumstances, and has an object to provide a bonding material manufacturing method and a bonded body manufacturing device each capable of enhancing the whole adhesiveness of a bonding material with respect to a glass member and a bonding target member.

### Solution to Problem

In order to attain the above object, a method for manufacturing a bonded body in accordance with an aspect of the present invention is a method for manufacturing a bonded body that includes a glass member, a bonding target member, and a bonding part via which the glass member and the bonding target member are bonded to each other, the method including: a jig preparing step of preparing a jig that includes a jig main body having a storage part and a pressing transparent member that is to be placed in the storage part; a placing step of (a) forming a laminate by placing, in the storage part, the glass member, the bonding target member, and at least one bonding material which is interposed between the glass member and the bonding target member and from which the bonding part is to be formed and (b) placing the laminate on plural urging members arranged in a bottom of the storage part so that a first surface of the laminate faces the plural urging members and placing the pressing transparent member on a second surface of the laminate which second surface is opposite to the first surface; after the placing step, a pressing step of pressing the second surface of the laminate via the pressing transparent member to thereby cause the first surface of the laminate to be pressed by urging forces of the plural urging members; and a bonding part forming step of forming, while pressing the laminate by the pressing step, the bonding part from the at least one bonding material to yield the bonded body.

In order to attain the above object, a bonded body manufacturing device in accordance with an aspect of the present invention is a bonded body manufacturing device used to carry out a method for manufacturing a bonded body that includes a glass member, a bonding target member, and a bonding part via which the glass member and the bonding target member are bonded to each other, the bonded body manufacturing device including: a jig main body having a storage part; and a pressing transparent member that is to be placed in the storage part, the storage part having a bottom in which plural urging members are arranged, the storage part being configured to store a laminate such that a first surface of the laminate faces the plural urging members, the laminate including the glass member, the bonding target member, and at least one bonding material which is interposed between the glass member and the bonding target member and from which the bonding part is to be formed, the pressing transparent member being to be placed on a second surface of the laminate which second surface is opposite to the first surface of the laminate, the pressing transparent member being configured to press the second surface of the laminate to thereby cause the first surface of the laminate to be pressed by urging forces of the plural urging members.

### Advantageous Effects of Invention

In accordance with an aspect of the present invention, it is possible to enhance the whole adhesiveness of a bonding material with respect to a glass member and a bonding target member.

### BRIEF DESCRIPTION OF DRAWINGS

FIG. 1 is a cross-sectional view of a bonded body in accordance with an embodiment of the present invention.

FIG. 2 is a plane view of a glass member in accordance with the embodiment of the present invention.

FIG. 3 is a plane view of a bonding target member in accordance with the embodiment of the present invention.

FIG. 4 is a cross-sectional view of a jig in accordance with an embodiment of the present invention shown in FIG. 6, taken along X-X line shown in FIG. 6.

FIG. 5 is a plane view of the jig shown in FIG. 4.

FIG. 6 is a bottom view of the jig shown in FIG. 4.

FIG. 7 is a flowchart illustrating an example of a flow of a method for manufacturing a bonded body in accordance with an embodiment of the present invention.

FIG. 8 is a view illustrating an example of a method for manufacturing a bonded body in accordance with an embodiment of the present invention.

### DESCRIPTION OF EMBODIMENTS

### Embodiment 1

The following description will discuss an embodiment according to an aspect of the present invention with reference to drawings. In an example described in Embodiment 1, a glass member 12 has one surface provided with plural bonding materials 14a each having a frame shape, and a bonding target member 13 has one surface provided with plural parts 15 such as electronic parts and plural spacers 16.

Note that, for convenience of explanation, some of the drawings show a part(s) of a configuration(s) in an exaggerated or simplified manner. Some of the drawings do not a real dimensional ratio of a part(s).

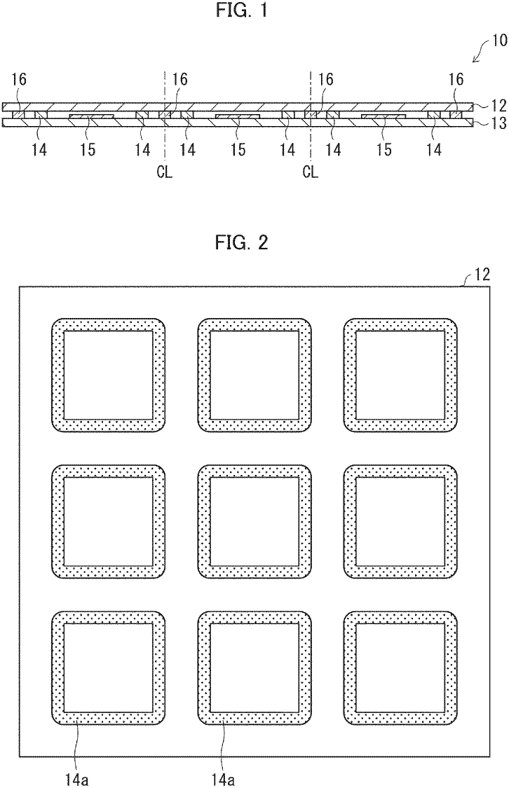

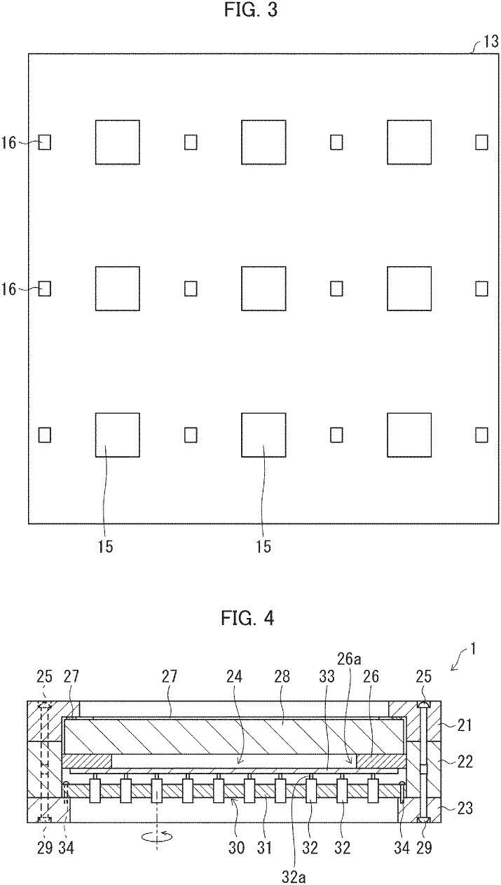

FIG. 1 is a cross-sectional view of a bonded body 10 in accordance with Embodiment 1 of the present invention. FIG. 2 is a plane view of the glass member 12 in accordance with Embodiment 1 of the present invention. FIG. 3 is a plane view of the bonding target member 13 in accordance with Embodiment 1 of the present invention.

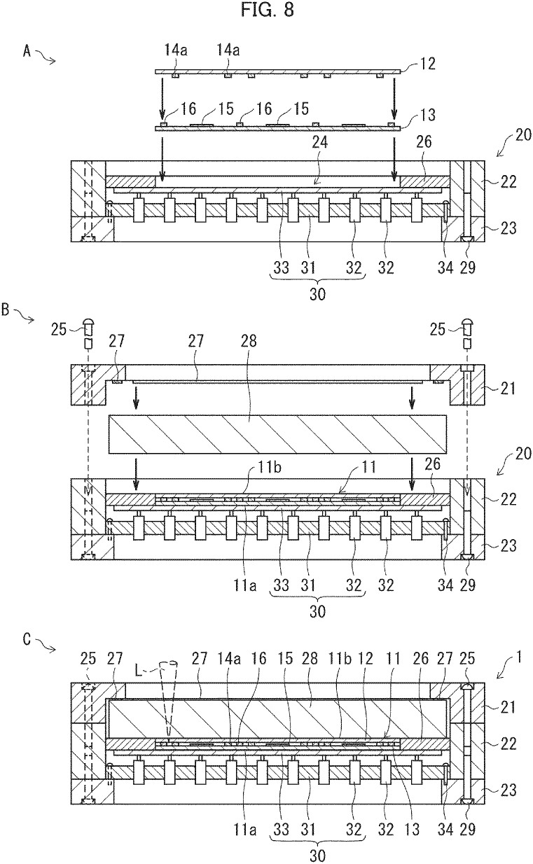

As shown in FIG. 1, the bonded body 10 includes the glass member 12, the bonding target member 13, and bonding parts 14 bonded to the glass member 12 and to the bonding target member 13. The bonded body 10 can be obtained from a laminate 11 (see state B in FIG. 8) made of the glass member 12, the bonding target member 13, and the bonding materials 14a interposed between the glass member 12 and the bonding target member 13.

As shown in FIG. 2, the glass member 12 is in the shape of a flat plate, and has a surface which is to be bonded to the bonding target member 13 and on which the plural bonding materials 14a each having a frame shape are arranged. The bonding materials 14a each having the frame shape are arranged so as to surround the respective parts 15 when the glass member 12 is bonded to the bonding target member 13.

As shown in FIG. 3, the bonding target member 13 is in the shape of a flat plate, and has the surface which is to be bonded to the glass member 12 and on which the plural parts 15 such as electronic parts are mounted and the spacers 16 are disposed between the parts 15.

### Glass Member 12

Examples of the glass member 12 encompass alkali-free glass (e.g., OA-10G or OA-11 available from Nippon Electric Glass Co., Ltd.), borosilicate glass (e.g., BDA available from Nippon Electric Glass Co., Ltd.), and soda-lime glass. For example, the glass member 12 has a thickness of not less than 50 µm and not more than 1000 µm, preferably of not less than 0.3 mm and not more than 0.7 mm, more preferably of approximately 0.5 mm. The glass member 12 has a size preferably of not less than 10 cm × 10 cm, more preferably of not less than 20 cm × 30 cm.

### Bonding Target Member 13

The bonding target member 13 includes a plate-shaped member such as a glass plate, a glass-ceramic plate, or a ceramic plate. Examples of the glass member encompass alkali-free glass (e.g., OA-10G or OA-11 available from Nippon Electric Glass Co., Ltd.), borosilicate glass (e.g., BDA available from Nippon Electric Glass Co., Ltd.), and soda-lime glass. The bonding target member 13 has a size preferably of not less than 10 cm × 10 cm, more preferably of not less than 20 cm × 30 cm.

The glass-ceramic plate serving as a substrate may be, for example, low temperature co-fired ceramics (LTCC) containing glass and a fireproof filler.

The ceramic plate may be, for example, a ceramic plate containing at least one kind selected from cordierite, willemite, alumina, aluminum nitride, a zirconium phosphate-based compound, zircon, zirconia, tin oxide, β-quartz solid solution, β-eucryptite, and β-spodumene.

For example, the bonding target member 13 has a thickness of not less than 50 µm and not more than 1000 µm, more preferably of approximately 0.7 mm.

The bonding target member 13 may have a functional film. The functional film may be, for example, a transparent conductive film or an oxide film. The transparent conductive film may be, for example, an indium-tin-oxide (ITO) film, a fluorine-doped tin oxide film (FTO) film, or an antimony tin oxide (ATO) film.

### Bonding Part 14

The bonding parts 14 are made from the bonding materials 14a. Each of the bonding materials 14a contains at least low melting glass, and can be produced with use of a paste prepared by mixing a low melting glass powder, a fireproof filler, a binder, a solvent, and/or the like. Specifically, the paste is disposed on the glass member 12 by a printing method such as a screen printing method or an application method such as a dispenser, and the paste is further subjected to heat treatment. Consequently, the paste is sintered on the glass member 12, so that the bonding parts 14 are formed.

The low melting glass powder can be, for example, at least one kind selected from bismuth oxide (Bi₂O₃)-based glass, silver oxide (Ag₂O)-based glass, and tellurium oxide (TeO₂)-based glass. Use of any of these types of low melting glass can enhance the bonding strength in a bonding part forming step. In order to enhance the efficiency of absorption of laser light L (see FIG. 8), the low melting glass powder preferably contains, in its glass composition, not less than 1 mol% of a transition metal oxide (e.g., CuO, Fe₂O₃).

The fireproof filler may be, for example, at least one kind selected from cordierite, zircon, tin oxide, niobium oxide, a zirconium phosphate-based ceramic, willemite, β-eucryptite, and β-quartz solid solution.

The fireproof filler has a median diameter (D₅₀) of preferably less than 2 µm. The fireproof filler has a 99% diameter (D₉₉) of preferably less than 15 µm. This can reduce the thicknesses of the bonding parts 14, thereby reducing a stress remaining on parts of the glass member 12 and parts of the bonding target member 13 which parts surrounding the bonding parts 14.

Each of the bonding materials 14a provided on the glass member 12 has a thickness preferably of not less than 0.5 µm and not more than 20 µm, more preferably of not less than 1 µm and not more than 10 µm. For example, each of the bonding materials 14a has a width preferably of not less than 1 µm and not more than 10000 µm, more preferably of not less than 10 µm and not more than 5000 µm, even more preferably of not less than 50 µm and not more than 1000 µm.

The description above has discussed the example in which the bonding materials 14a are formed on the glass member 12, but the present invention is not limited to this example. Alternatively, the bonding materials 14a may be formed on the bonding target member 13.

### Part 15

Each of the bonded body 10 and the laminate 11 may include the parts 15 interposed between the glass member 12 and the bonding target member 13. Examples of each of the parts 15 encompass optical elements (e.g., a laser module, a light-emitting diode (LED) light source, an optical sensor, an image pickup device, and an optical switch), display parts (e.g., a liquid crystal display part and an organic electroluminescence (EL) display part), a solar cell, a vibration sensor, and an acceleration sensor.

### Spacer 16

In Embodiment 1, the spacers 16 are interposed between the glass member 12 and the bonding target member 13 in the bonded body 10. The spacers 16 are provided to prevent a distance between the glass member 12 and the bonding target member 13 from dropping below a given value.

When viewed in a plane view, the spacers 16 are disposed outside the bonding parts 14 each having the frame shape, i.e., between adjacent ones of the bonding parts 14. Preferably, when viewed in a plane view, the spacers 16 are disposed inside and outside the bonding parts 14 each having the frame shape. With this configuration, the distance between the glass member 12 and the bonding target member 13 can be kept constant more reliably. The present invention is not limited to this configuration. Alternatively, when viewed in a plane view, the spacers 16 may be disposed only inside the bonding parts 14 each having the frame shape.

In an example shown in FIG. 3, the spacers 16 are disposed on the bonding target member 13. However, the present invention is not limited to this. Alternatively, the spacers 16 may be disposed on the glass member 12. Further alternatively, the spacers 16 may be omitted.

Each of the spacers 16 may be made of a material such as a sintered body produced from the above-described glass powder and/or the like, a sintered body of a ceramic, or a resin molded body.

### Bonded Body 10

Specific examples of application of the bonded body 10 encompass organic EL devices (e.g., an organic EL display and an organic EL illumination device), solar cells (e.g., a dye-sensitized solar cell, an all-solid-state dye-sensitized solar cell, a perovskite-type solar cell, an organic thin-film solar cell, and a CIGS-based thin-film compound solar cell), a sensor package (e.g., a micro-electromechanical systems (MEMS) package), and an LED package that emits light such as deep ultraviolet light.

For example, as shown in FIG. 1, the bonded body 10 may be cut at positions indicated by the cutting-plane lines CL, i.e., at the positions between the plural bonding parts 14 each having the frame shape. The cutting method may be, for example, a method of bending and cutting the bonded body 10 along a scribe line formed with a tip wheel or laser light.

In an example shown in FIG. 1, the bonded body 10 is cut at the positions of the spacers 16 between the plural bonding parts 14 each having the frame shape. However, the present invention is not limited to this. Alternatively, the bonded body 10 may be cut at a position(s) other than the spacers 16. In a case where the spacers 16 are outside the bonding parts 14 each having the frame shape, the spacers 16 may not remain in the bonded body 10 after the cutting.

The following description will discuss details of one example of a configuration of main parts of a jig 1 in accordance with Embodiment 1.

### Jig 1

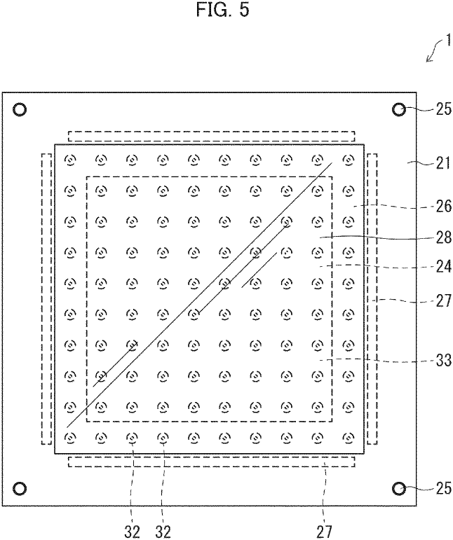

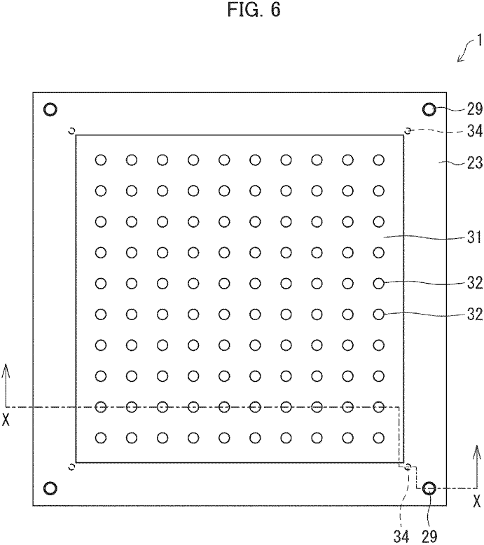

FIG. 4 is a cross-sectional view of the jig 1 in accordance with an embodiment of the present invention shown in FIG. 6, taken along X-X line shown in FIG. 6. FIG. 5 is a plane view of the jig 1 shown in FIG. 4. FIG. 6 is a bottom view of the jig 1 shown in FIG. 4.

As shown in FIGS. 4, 5, and 6, the jig 1 includes a jig main body 20 (see FIG. 8), a frame body 21 for pressing (pressing frame body 21), a transparent member 28 for pressing (pressing transparent member 28).

The jig main body 20 includes a base frame body 23 serving as a support base, an urging part 30 placed on the base frame body 23 and fixed to the base frame body 23 by screws 34, and an intermediate frame body 22 fixed to the base frame body 23 by screws 29. Inside the jig main body 20, a storage part 24 is formed that has a bottom constituted by the urging part 30 and a circumferential wall constituted by the base frame body 23 and the intermediate frame body 22. In the storage part 24, the bonding target member 13 and the glass member 12 of the laminate 11 are placed in order, and then the pressing transparent member 28 is placed.

The urging part 30 urges a lower surface (first surface) 11a (see FIG. 8) of the laminate 11 stored in the storage part 24. The urging part 30 includes plural plungers (urging members) 32 resisting a compressive force, a support base 31 to which the plungers 32 are attached, and an urging plate 33 disposed between the plungers 32 and the bonding target member 13 of the laminate 11.

As shown in FIGS. 5 and 6, the plungers 32 are arranged uniformly over the entire surface of the support base 31. A distance between the center axes of adjacent ones of the plungers 32 is not less than 3 mm and not more than 10 mm, preferably approximately 5 mm.

As shown in FIG. 5, the plungers 32 are arranged not only below the laminate 11 but also below a positioning member 26, that is, the plungers 32 are arranged in an area wider than the laminate 11. This makes it possible to urge the lower surface 11a of the laminate 11 more uniformly.

Each of the plungers 32 has (i) a compression coil spring (not shown) provided inside the plunger 32 and (ii) a pin 32a to be urged by the compression coil spring. The plungers 32 are adjusted to exert substantially equal urging forces against the bonding target member 13. Specifically, each of the plungers 32 has a screw formed around its axis. Rotating the plungers 32 from the bottom surface side of the storage part 24 enables adjustment of the plungers 32 so that the heights of the plungers 32 protruded into the storage part 24 become substantially the same.

The urging plate 33 is disposed for the purpose of more uniformly transmitting the urging forces of the plungers 32 to the bonding target member 13. The urging plate 33 has a flat upper surface so as to be in surface contact with a lower surface of the bonding target member 13. The urging plate 33 is made of, for example, a metal plate such as a stainless steel plate, a glass plate, a ceramic plate, or a resin plate.

Note that each of the urging members of the urging part 30 is not limited to the one including the plunger 32. Alternatively, for example, the urging member may be a compression coil spring, a plate spring, or a polymeric material having elasticity such as rubber. The urging members may be at least one kind selected from the above-listed members, or may be a combination of one or more kinds selected therefrom.

The pressing transparent member 28 is preferably a glass plate having a light-transmitting property. From the viewpoint of mechanical strength and/or the like, the pressing transparent member 28 has a thickness preferably of not less than 1.5 mm, particularly preferably of not more than 2.0 mm. From the viewpoint of transmittance of laser light, the pressing transparent member 28 has a thickness preferably of not more than 5.0 mm, particularly preferably of not more than 3.0 mm. The pressing transparent member 28 is preferably thicker than the glass member 12, and is particularly preferably thicker than the glass member 12 by not less than 1 mm. From the viewpoint of shape stability, the pressing transparent member 28 has a modulus of elasticity preferably of not less than 65 GPa and not more than 85 GPa.

The pressing frame body 21 is positioned so as to cover, via an elastic member 27, at least a part of an upper surface of the pressing transparent member 28. The pressing frame body 21 is fixed to the intermediate frame body 22 by pressing screws 25. With this, by screwing the pressing screws 25 toward the intermediate frame body 22, it is possible to press an upper surface (second surface) 11b (see FIG. 8) of the laminate 11 via the pressing transparent member 28.

As a result of pressing the upper surface 11b of the laminate 11 via the pressing transparent member 28, the lower surface 11a of the laminate 11 is pressed by the urging forces of the urging parts 30.

### Method for Manufacturing Bonded Body 10

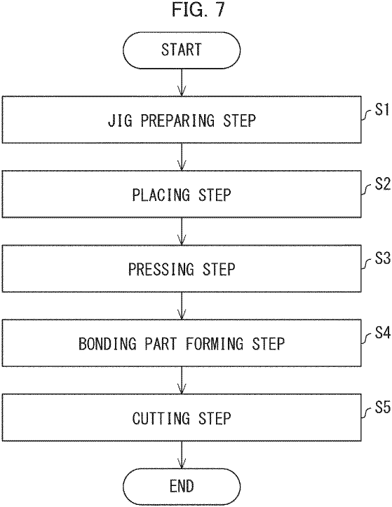

The following description will discuss, with reference to FIGS. 7 and 8, an example of a method for manufacturing the bonded body 10 in accordance with Embodiment 1.

FIG. 7 is a flowchart illustrating an example of a flow of a method for manufacturing the bonded body 10 in accordance with an embodiment of the present invention. FIG. 8 is a view illustrating an example of a method for manufacturing the bonded body 10 in accordance with an embodiment of the present invention.

As shown in FIG. 7, the method for manufacturing the bonded body 10 includes step S1 that is a jig preparing step, step S2 that is a placing step, step S3 that is a pressing step, step S4 that is a bonding part forming step, and step S5 that is a cutting step.

Step S1 that is the jig preparing step prepares the jig 1 in which the laminate 11 is to be stored and with which the laminate 11 is to be pressed.

Step S2 that is the placing step first places the bonding target member 13 on the urging plate 33 in the jig 1 so that the surface of the bonding target member 13 on which surface the parts 15 are mounted faces an upper side, as indicated by state A in FIG. 8. Then, step S2 that is the placing step places the glass member 12 over the bonding target member 13 so that the surface of the glass member 12 on which surface the bonding materials 14a are formed faces a lower side. Consequently, inside the storage part 24, the laminate 11 is formed that includes the bonding target member 13, the glass member 12, and the bonding materials 14a interposed between the glass member 12 and the bonding target member 13.

On the urging plate 33, the positioning member 26 may be disposed. In order that the positioning member 26 can reliably give an urging force, the positioning member 26 preferably has a thickness that is smaller than a thickness of the laminate 11. The positioning member 26 has a frame shape, and has, in its inside, a storage space 26a whose shape is substantially identical to an outer shape of the laminate 11. By setting the laminate 11 so that the laminate 11 is stored in the storage space 26a (see FIG. 4), the laminate 11 can be placed accurately at a proper position. For laminates 11 having different sizes, different positioning members 26 corresponding to the respective laminates 11 may be used. With this, laminates 11 having different sizes can be placed at their respective proper positions.

Next, as indicated by state B in FIG. 8, the pressing transparent member 28 is placed on the upper surface 11b of the laminate 11. The pressing frame body 21 is fixed to the intermediate frame body 22 by the pressing screws 25 so as to cover a peripheral part of an upper surface of the pressing transparent member 28.

Step S3 that is the pressing step screws the pressing screws 25 toward the intermediate frame body 22 so as to cause the upper surface 11b of the laminate 11 to be pressed via the pressing transparent member 28. As a result of pressing the upper surface 11b of the laminate 11 via the pressing transparent member 28, the lower surface 11a of the laminate 11 is pressed by the urging forces of the urging parts 30.

Step S4 that is the bonding part forming step forms, from the bonding materials 14a, the bonding parts 14 bonded to the glass member 12 and the bonding target member 13, while pressing the laminate 11 by step S3 that is the pressing step. Consequently, the bonded body 10 can be formed from the laminate 11.

Step S4 that is the bonding part forming step according to Embodiment 1 heats the bonding materials 14a with laser light L. To be more specific, in step S4 that is the bonding part forming step, the laser light L is allowed to pass through the pressing transparent member 28 and the glass member 12 so that the bonding materials 14a are irradiated with the laser light L, as indicated by state C in FIG. 8.

A wavelength of the laser light L is not limited to any particular one, provided that the laser light L having the wavelength can heat the bonding materials 14a. The wavelength of the laser light L is preferably of 600 nm to 1600 nm, for example. A light source that emits the laser light L is preferably a semiconductor laser, for example.

After step S4 that is the bonding part forming step, step S5 that is the cutting step carries out the cutting step of cutting the bonded body 10 at positions (CL in FIG. 1) between the plural bonding parts 14 each having the frame shape, so as to obtain plural bonded bodies.

The following will discuss the effects of Embodiment 1.

(1) In the method for manufacturing the bonded body 10, step 1 that is the jig preparing step prepares the jig 1 that includes the jig main body 20 having the storage part 24 and the pressing transparent member 28 to be placed in the storage part 24.

Step 2 that is the placing step forms the laminate 11 by placing, in the storage part 24, the glass member 12, the bonding target member 13, and the bonding materials 14a which are interposed between the glass member 12 and the bonding target member 13 and from which the bonding parts 14 are to be formed. In addition, step 2 that is the placing step places the laminate 11 on the plural urging members 32 arranged in the bottom of the storage part 24 so that the lower surface 11a of the laminate 11 faces the plural urging members 32, and places the pressing transparent member 28 on the upper surface 11b of the laminate 11.

Step 3 that is the pressing step presses the upper surface 11b of the laminate 11 via the pressing transparent member 28 to thereby cause the lower surface 11a of the laminate 11 to be pressed by urging forces of the plural urging members 32.

Step 4 that is the bonding part forming step forms, while pressing the laminate 11, the bonding parts 14 from the bonding materials 14a, thereby yielding the bonded body 10.

In accordance with the above method, step 3 that is the pressing step presses the upper surface 11b of the laminate 11 via the pressing transparent member 28, so as to cause the lower surface 11a of the laminate 11 to be pressed by the urging forces of the plural urging members 32. Consequently, a force applied to the bonding materials 14a between the glass member 12 and the bonding target member 13 is adjusted by the urging forces. This can stabilize a force applied between the glass member 12 and the bonding materials 14a and a force applied between the bonding target member 13 and the bonding materials 14a.

Thus, it is possible to easily enhance the whole adhesiveness of the bonding materials 14a with respect to the glass member 12 and the bonding target member 13. Consequently, in the bonded body 10 obtained as a result of step S4 that is the bonding part forming step, it is possible to reduce poor bonding between the glass member 12 and the bonding target member 13 and/or to enhance reliability of the bonding parts 14, for example.

(2) Step 4 that is the bonding part forming step forms the bonding parts 14 by heating the bonding materials 14a through irradiation of the bonding materials 14a with the laser light L having been caused to pass through the pressing transparent member 28 and the glass member 12.

This enables local heating with the laser light L. Therefore, it is possible to prevent an undesirable temperature rise at a portion(s) other than the bonding materials 14a, for example.

(3) Step 3 that is the pressing step causes the pressing frame body 21 to uniformly press the upper surface 11b of the laminate 11 via the pressing transparent member 28. The plural urging members 32, which exert substantially equal urging forces, uniformly urge the lower surface 11a of the laminate 11 via the urging plate 33.

With this, it is possible to carry out the bonding part forming step that is step S4 in a state in which the whole adhesiveness of the bonding materials 14a with respect to the glass member 12 and the bonding target member 13 is further enhanced. As a result, in the bonded body 10 to be obtained, it is possible to further reduce poor bonding between the glass member 12 and the bonding target member 13 and/or to further enhance reliability of the bonding parts 14.

(4) In step 2 that is the placing step, thanks to the spacers 16 further provided to the laminate 11 at positions between the glass member 12 and the bonding target member 13, a gap between the glass member 12 and the bonding target member 13 can be kept constant. As a result, it is possible to avoid a phenomenon that the parts 15 such as electronic parts between the glass member 12 and the bonding target member 13 receive an undesired compressive force in step 3 that is the pressing step and/or step 4 that is the bonding part forming step. Particularly, a laminate 11 having a larger size (i.e., a laminate 11 including a glass member 12 and a bonding target member 13 each having a larger area) typically tends to have a smaller gap at and around a center of the laminate 11, Meanwhile, Embodiment 1 can effectively avoid such a disadvantageous phenomenon.

### Variations

Embodiment 1 can be varied as below. Embodiment 1 and any of the following variations can be combined, provided that this does not technical contradiction.

Step S4 that is the bonding part forming step is not limited to the step of carrying out the heating with the laser light L. Alternatively, for example, step S4 that is the bonding part forming step may be a step of carrying out heating with a light beam (e.g., an infrared lamp) other than the laser light L or a step of curing, with an ultraviolet ray, bonding materials containing an ultraviolet curing resin.

The pressing transparent member 28 may be made of a material other than glass. The pressing transparent member 28 may have a layered structure constituted by layers of different types of materials. For example, the pressing transparent member 28 may have a structure in which a glass plate and an elastic member 27 are integrated together.

The elastic member 27 may be integrated with the pressing frame body 21, rather than with the pressing transparent member 28.

In step S2 that is the placing step, the laminate 11 may be placed in the storage part 24 of the jig main body 20 with the laminate 11 being placed upside down so that the bonding target member 13 of the laminate 11 is positioned adjacent to the pressing transparent member 28.

In step S3 that is the pressing step, the bonding target member 13 may be pressed toward the glass member 12, and the glass member 12 may be urged toward the pressing transparent member 28.

The number of bonding materials 14a each having the frame shape in the laminate 11 is not limited to any particular one, and may be one or two or more.

Each of the bonding materials 14a may be in the shape of a continuous frame or a discontinuous frame.

The shape of each bonding material 14a and the shape of each bonding part 14 are not limited to the shapes that define air-tight sections between the glass member 12 and the bonding target member 13. The shape of each bonding material 14a and the shape of each bonding part 14 only need to be shapes with which the glass member 12 and the bonding target member 13 can be bonded to each other.

The spacers 16 of the laminate 11 may be omitted. The number, the shapes, the sizes, and the like of the spacers 16 can be changed as appropriate.

### Conclusion

As described above, a method for manufacturing a bonded body in accordance with an aspect of the present invention is a method for manufacturing a bonded body that includes a glass member, a bonding target member, and a bonding part via which the glass member and the bonding target member are bonded to each other, the method including: a jig preparing step of preparing a jig that includes a jig main body having a storage part and a pressing transparent member that is to be placed in the storage part; a placing step of (a) forming a laminate by placing, in the storage part, the glass member, the bonding target member, and at least one bonding material which is interposed between the glass member and the bonding target member and from which the bonding part is to be formed and (b) placing the laminate on plural urging members arranged in a bottom of the storage part so that a first surface of the laminate faces the plural urging members and placing the pressing transparent member on a second surface of the laminate which second surface is opposite to the first surface; after the placing step, a pressing step of pressing the second surface of the laminate via the pressing transparent member to thereby cause the first surface of the laminate to be pressed by urging forces of the plural urging members; and a bonding part forming step of forming, while pressing the laminate by the pressing step, the bonding part from the at least one bonding material to yield the bonded body.

With the above method, the pressing step presses the second surface of the laminate via the pressing transparent member to thereby cause the first surface of the laminate to be pressed by the urging forces of the plural urging members. With this, when a pressure is applied to the laminate via the pressing transparent member, a force applied to the bonding material between the glass member and the bonding target member is adjusted by the urging forces. This can stabilize a force applied between the glass member and the bonding material and a force applied between the bonding target member and the bonding material. Consequently, it is possible to enhance the whole adhesiveness of the bonding material with respect to the glass member and the bonding target member.

The method for manufacturing the bonded body in accordance with the aspect of the present invention may be configured such that, in the bonding part forming step, the bonding part is formed by heating the at least one bonding material through irradiation of the at least one bonding material with laser light having been caused to pass through the pressing transparent member and the glass member.

With the above method, it is possible to carry out local heating with the laser light. Therefore, it is possible to prevent an undesirable temperature rise at a portion(s) other than the bonding material, for example.

The method for manufacturing the bonded body in accordance with the aspect of the present invention may be configured such that the urging forces of the plural urging members are substantially equal to each other.

With the above method, the urging forces of the plural urging members applied to the lower surface of the laminate are made uniform. Consequently, it is possible to prevent a phenomenon that the adhesiveness of the bonding material is partially reduced.

The method for manufacturing the bonded body in accordance with the aspect of the present invention may be configured such that, in the placing step, an urging plate is placed between the plural urging members and the first surface of the laminate, and in the pressing step, the first surface of the laminate is pressed by the plural urging members via the urging plate.

With the above method, the urging forces of the plural urging members are made uniform by the urging plate. Consequently, the urging forces of the urging members can be transmitted more uniformly to the lower surface of the laminate, thereby enhancing the whole adhesiveness of the bonding material with respect to the laminate.

The method for manufacturing the bonded body in accordance with the aspect of the present invention may be configured such that, in the jig preparing step, a pressing frame body is further prepared that is to be placed to cover at least a part of a second surface of the pressing transparent member, and in the pressing step, the pressing frame body presses the pressing transparent member.

With the above method, the pressure of the pressing frame body can be transmitted more uniformly to the upper surface of the laminate, thereby enhancing the whole adhesiveness of the bonding material with respect to the laminate.

The method for manufacturing the bonded body in accordance with the aspect of the present invention may be configured such that the glass member is a glass plate being in a shape of a flat plate, the bonding target member is a glass plate being in a shape of a flat plate, the at least one bonding material in the laminate in the placing step contains at least low melting glass, and the pressing transparent member is a glass plate. Note that the low melting glass refers to glass that is softened and deformed upon subjected to the bonding part forming step. For example, the low melting glass may be glass having a softening point of not more than 500° C. when measured by differential thermal analysis.

With the above method, it is possible to carry out local heating with the laser light, since the glass allows laser light to pass therethrough. With this, it is possible to prevent an undesirable temperature rise at a portion(s) other than the bonding material. In addition, use of the bonding material containing the low melting glass makes it possible to more reliably prevent an undesirable temperature rise at a portion(s) other than the bonding material, since such a bonding material can be melted at a lower temperature. In addition, this can further enhance the bonding strength.

The method for manufacturing the bonded body in accordance with the aspect of the present invention may be configured such that, in the placing step, the laminate is placed at a position defined by a positioning member placed in the storage part.

With the above method, which employs the positioning member, it is possible to place the laminate accurately at an optimum position in the storage part. This makes it possible to uniformly press the entire laminate, and also enables accurate irradiation of the bonding material with the laser light.

The method for manufacturing the bonded body in accordance with the aspect of the present invention may be configured such that the at least one bonding material included in the laminate includes plural bonding materials each having a frame shape.

With the above method, it is possible to partition, by bonding parts each having a frame shape, parts such as electronic parts that are interposed between the glass member and the bonding target member.

The method for manufacturing the bonded body in accordance with the aspect of the present invention may be configured such that the laminate further includes a spacer interposed between the glass member and the bonding target member.

With the above method, it is possible to avoid a phenomenon that the parts such as electronic parts interposed between the glass member and the bonding target member receive an undesired compressive force in the pressing step and/or the bonding part forming step.

The method for manufacturing the bonded body in accordance with the aspect of the present invention may further include, after the bonding part forming step, a cutting step of cutting the bonded body at a position between plural bonding parts each having a frame shape, the plural bonding parts being formed from the plural bonding materials each having the frame shape.

With the above method, for example, it is possible to manufacture a plurality of packages at once. That is, it is possible to manufacture the packages efficiently.

The method for manufacturing the bonded body in accordance with the aspect of the present invention may be configured such that the pressing transparent member is a glass plate having a thickness of not less than 1.5 mm and not more than 5.0 mm and a modulus of elasticity of not less than 65 GPa and not more than 85 GPa.

A bonded body manufacturing device in accordance with an aspect of the present invention is a bonded body manufacturing device used to carry out a method for manufacturing a bonded body that includes a glass member, a bonding target member, and a bonding part via which the glass member and the bonding target member are bonded to each other, the bonded body manufacturing device including: a jig main body having a storage part; and a pressing transparent member that is to be placed in the storage part, the storage part having a bottom in which plural urging members are arranged, the storage part being configured to store a laminate such that a first surface of the laminate faces the plural urging members, the laminate including the glass member, the bonding target member, and at least one bonding material which is interposed between the glass member and the bonding target member and from which the bonding part is to be formed, the pressing transparent member being to be placed on a second surface of the laminate which second surface is opposite to the first surface of the laminate, the pressing transparent member being configured to press the second surface of the laminate to thereby cause the first surface of the laminate to be pressed by urging forces of the plural urging members.

With the above configuration, as a result of pressing the upper surface (second surface) of the laminate via the pressing transparent member, the lower surface (first surface) of the laminate is pressed by the urging forces of the plural urging members. With this, when a pressure is applied to the laminate via the pressing transparent member, a force applied to the bonding material between the glass member and the bonding target member is adjusted by the urging forces. This can stabilize a force applied between the glass member and the bonding material and a force applied between the bonding target member and the bonding material. Consequently, it is possible to enhance the whole adhesiveness of the bonding material with respect to the glass member and the bonding target member.

The present invention is not limited to the embodiments, but can be altered by a skilled person in the art within the scope of the claims. The present invention also encompasses, in its technical scope, any embodiment derived by combining technical means disclosed in differing embodiments.

### REFERENCE SIGNS LIST

1: Jig
10: Bonded body
11: Laminate
11a: Lower surface (first surface)
11b: Upper surface (second surface)
12: Glass member
13: Bonding target member
14: Bonding part
14a: Bonding material
16: Spacer
20: Jig main body
21: Pressing frame body
24: Storage part
26: Positioning member
28: Pressing transparent member
32: Urging member
33: Urging plate

1. A method for manufacturing a bonded body that includes a glass member, a bonding target member, and a bonding part via which the glass member and the bonding target member are bonded to each other,
said method comprising:
a jig preparing step of preparing a jig that includes a jig main body having a storage part and a pressing transparent member that is to be placed in the storage part;
a placing step of (a) forming a laminate by placing, in the storage part, the glass member, the bonding target member, and at least one bonding material which is interposed between the glass member and the bonding target member and from which the bonding part is to be formed and (b) placing the laminate on plural urging members arranged in a bottom of the storage part so that a first surface of the laminate faces the plural urging members and placing the pressing transparent member on a second surface of the laminate which second surface is opposite to the first surface;
after the placing step, a pressing step of pressing the second surface of the laminate via the pressing transparent member to thereby cause the first surface of the laminate to be pressed by urging forces of the plural urging members; and
a bonding part forming step of forming, while pressing the laminate by the pressing step, the bonding part from said at least one bonding material to yield the bonded body.

2. The method as set forth in claim 1, wherein
in the bonding part forming step, the bonding part is formed by heating said at least one bonding material through irradiation of said at least one bonding material with laser light having been caused to pass through the pressing transparent member and the glass member.

3. The method as set forth in claim 1, wherein
the urging forces of the plural urging members are substantially equal to each other.

4. The method as set forth in claim 1, wherein
in the placing step, an urging plate is placed between the plural urging members and the first surface of the laminate, and
in the pressing step, the first surface of the laminate is pressed by the plural urging members via the urging plate.

5. The method as set forth in claim 1, wherein
in the jig preparing step, a pressing frame body is further prepared that is to be placed to cover at least a part of a second surface of the pressing transparent member, and
in the pressing step, the pressing frame body presses the pressing transparent member.

6. The method as set forth in claim 1, wherein
the glass member is a glass plate being in a shape of a flat plate,
the bonding target member is a glass plate being in a shape of a flat plate,
said at least one bonding material in the laminate in the placing step contains at least low melting glass, and
the pressing transparent member is a glass plate.

7. The method as set forth in claim 1, wherein
in the placing step, the laminate is placed at a position defined by a positioning member placed in the storage part.

8. The method as set forth in claim 1, wherein
said at least one bonding material included in the laminate comprises plural bonding materials each having a frame shape.

9. The method as set forth in claim 8, wherein
the laminate further includes a spacer interposed between the glass member and the bonding target member.

10. The method as set forth in claim 8, further comprising:
after the bonding part forming step, a cutting step of cutting the bonded body at a position between plural bonding parts each having a frame shape, the plural bonding parts being formed from the plural bonding materials each having the frame shape.

11. The method as set forth in claim 1, wherein
the pressing transparent member is a glass plate having a thickness of not less than 1.5 mm and not more than 5.0 mm and a modulus of elasticity of not less than 65 GPa and not more than 85 GPa.

12. A bonded body manufacturing device used to carry out a method for manufacturing a bonded body that includes a glass member, a bonding target member, and a bonding part via which the glass member and the bonding target member are bonded to each other,
said bonded body manufacturing device comprising:
a jig main body having a storage part; and
a pressing transparent member that is to be placed in the storage part,
the storage part having a bottom in which plural urging members are arranged,
the storage part being configured to store a laminate such that a first surface of the laminate faces the plural urging members, the laminate including the glass member, the bonding target member, and at least one bonding material which is interposed between the glass member and the bonding target member and from which the bonding part is to be formed,
the pressing transparent member being to be placed on a second surface of the laminate which second surface is opposite to the first surface of the laminate,
the pressing transparent member being configured to press the second surface of the laminate to thereby cause the first surface of the laminate to be pressed by urging forces of the plural urging members.
